(19) United States
(12) Patent Application Publication
(10) Pub. No.: US 2013/0183799 A1
(43) Pub. Date: Jul. 18, 2013

(54) METHOD FOR MANUFACTURING SEMICONDUCTOR DEVICE

(71) Applicants: Jun SASAKI, Tokyo (JP); Tadashi KOYANAGI, Tokyo (JP)

(72) Inventors: Jun SASAKI, Tokyo (JP); Tadashi KOYANAGI, Tokyo (JP)

(73) Assignee: ELPIDA MEMORY, INC., Tokyo (JP)

(21) Appl. No.: 13/467,464

(22) Filed: May 9, 2012

(30) Foreign Application Priority Data
Jan. 17, 2012 (JP) 2012-007016

(51) Int. Cl. H01L 23/00

(52) U.S. Cl. CPC H01L 24/11
USPC 438/118; 438/613

(57) ABSTRACT

Provided is a method for manufacturing a semiconductor device, which includes: preparing a semiconductor wafer; and peeling off an adhesive layer from the semiconductor wafer. The prepared semiconductor wafer includes at least one semiconductor chip having a bump electrode group formed by arraying bump electrodes in a matrix, and the adhesive layer formed on one surface having the bump electrodes. The bump electrode group is formed by arraying the bump electrodes so that the number of bump electrodes in a second direction can be smaller than that in a first direction. To peel off the adhesive layer from the semiconductor wafer, the adhesive layer is peeled off from the semiconductor wafer along the first direction from one end side of the semiconductor wafer.

This application is based upon and claims the benefit of priority from Japanese patent application No. 2012-7016, filed on Jan. 17, 2012, the disclosure of which is incorporated herein in its entirety by reference.

### BACKGROUND OF THE INVENTION

1. Technical Field

The present invention relates to a method for manufacturing a semiconductor device, which includes peeling-off of an adhesive layer from a semiconductor wafer.

2. Description of Related Art

For example, many semiconductor chips such as dynamic random access memories (DRAMs) are formed en bloc on the semiconductor wafer. Dividing the semiconductor wafer into chips enables acquisition of many semiconductor chips. According to a method for manufacturing a semiconductor device described in JP2011-181822A, the semiconductor wafer is mounted on a support substrate via an adhesive layer, and a penetrating electrode is formed on the semiconductor wafer. Then, the semiconductor wafer is divided into semiconductor chips in a state where the semiconductor wafer is mounted on the support substrate. A dicing tape is then stuck to the rear surface of the semiconductor wafer, namely, a surface opposite the support substrate, and the support substrate and the adhesive layer are peeled off from the semiconductor wafer. Then, each divided semiconductor chip is picked up from the dicing tape. A chip-on-chip (CoC) semiconductor device is manufactured by stacking the picked-up semiconductor chips.

The semiconductor wafer on which the penetrating electrode is formed has a thickness of about 50 micrometers. When penetrating electrodes and bump electrodes are formed at equal pitches in one direction, defects described below may occur to create a possibility that manufacturing efficiency and reliability of the semiconductor device will be reduced.

According to the method for manufacturing a semiconductor device described in JP2011-181822A, the adhesive layer that bonds the semiconductor wafer and the support substrate is formed to bury the bump electrode on the semiconductor wafer. The part of the adhesive layer corresponding to the bump electrode is accordingly thinner than other parts. Consequently, during the peeling-off of the adhesive layer from the semiconductor wafer, the adhesive layer is easily cut in the arraying direction of bumps. When the adhesive layer is cut during its peeling-off, the adhesive layer is left on the wafer.

The penetrating electrode is formed by burying a hole formed in a silicon substrate. Therefore, in the case of a wafer having a semiconductor chip where penetrating electrodes are arrayed in one direction, cracks easily occur in the arraying direction of the penetrating electrodes during the peeling-off of the adhesive layer.

In the case of the wafer having the semiconductor chip where the penetrating electrodes are arrayed in one direction, when the dicing tape is attached to the wafer, a large void may be generated between the wafer and the dicing tape. This occurs because bump electrodes arrayed long in one direction become barriers to block discharging of air between the wafer and the dicing tape, thereby trapping the air near the bump electrodes. Consequently, the dicing tape may not be satisfactorily stuck to the semiconductor wafer.

It is therefore desired that a manufacturing method of a semiconductor device capable of satisfactorily peeling off an adhesive layer and a manufacturing method of a semiconductor device capable of satisfactorily attaching a dicing tape to a semiconductor wafer be provided.

### SUMMARY

A method for manufacturing a semiconductor device according to an embodiment includes: preparing a semiconductor wafer; and peeling off an adhesive layer from the semiconductor wafer. The prepared semiconductor wafer includes at least one semiconductor chip having a bump electrode group formed by arraying bump electrodes in a matrix, and the adhesive layer formed on one surface having the bump electrodes. In this bump electrode group, the number of bump electrodes in a second direction is smaller than that in a first direction. To peel off the adhesive layer from the semiconductor wafer, the adhesive layer is peeled off from the semiconductor wafer along the first direction from one end side of the semiconductor wafer.

In the adhesive layer bonded to the semiconductor wafer, compared with cuts in a direction along the bump electrodes in the first direction where the number of arrayed bump electrodes is large, it is difficult for cuts to occur in the second direction where the number of arrayed bump electrodes is small. As a result, peeling off the adhesive layer from the semiconductor wafer in the first direction prevents cuts from occurring in the adhesive layer that is being peeled off and ensures that the adhesive layer does not remains on the semiconductor wafer. Further, in the first direction where the number of arrayed bump electrodes is large, resistance of the semiconductor wafer to an external force is relatively high. This is advantageous in that it is difficult for cracks to occur in the semiconductor wafer during the peeling-off of the adhesive layer.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a plan view schematically illustrating the configuration of a semiconductor wafer;

FIG. 2 is a plan view illustrating the arrangement of bumps in one semiconductor chip formed on the semiconductor wafer;

FIGS. 3A to 3D are flowcharts illustrating a method for manufacturing a semiconductor device according to an embodiment;

FIGS. 4A to 4D are flowcharts illustrating a method for attaching a dicing tape to the semiconductor wafer;

FIGS. 5A and 5B are schematic pan views illustrating a method for attaching a dicing tape to the semiconductor wafer;

FIGS. 6A to 6C are flowcharts illustrating a method for peeling off a support from the semiconductor wafer;

FIGS. 7A to 7D are flowcharts illustrating a method for peeling off an adhesive material from the semiconductor wafer;

FIGS. 8A and 8B are schematic pan views illustrating the method for peeling off the adhesive material from the semiconductor wafer;

FIGS. 9A to 9D are flowcharts illustrating an example of a method for forming a chip laminated body where semiconductor chips are stacked on one another;

FIGS. 10A to 10D are flowcharts illustrating an example of a method for manufacturing a CoC semiconductor device that includes semiconductor chips stacked on one another;

FIGS. 11A and 11B are plan views illustrating one semiconductor chip formed on a semiconductor wafer according to another embodiment; and

FIGS. 12A and 12B are plan views illustrating one semiconductor chip formed on a semiconductor wafer according to yet another embodiment.

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

The present invention can be applied to a general method for manufacturing a semiconductor device, which includes adhering an adhesive tape to a semiconductor wafer, and/or peeling off an adhesive layer from the semiconductor wafer.

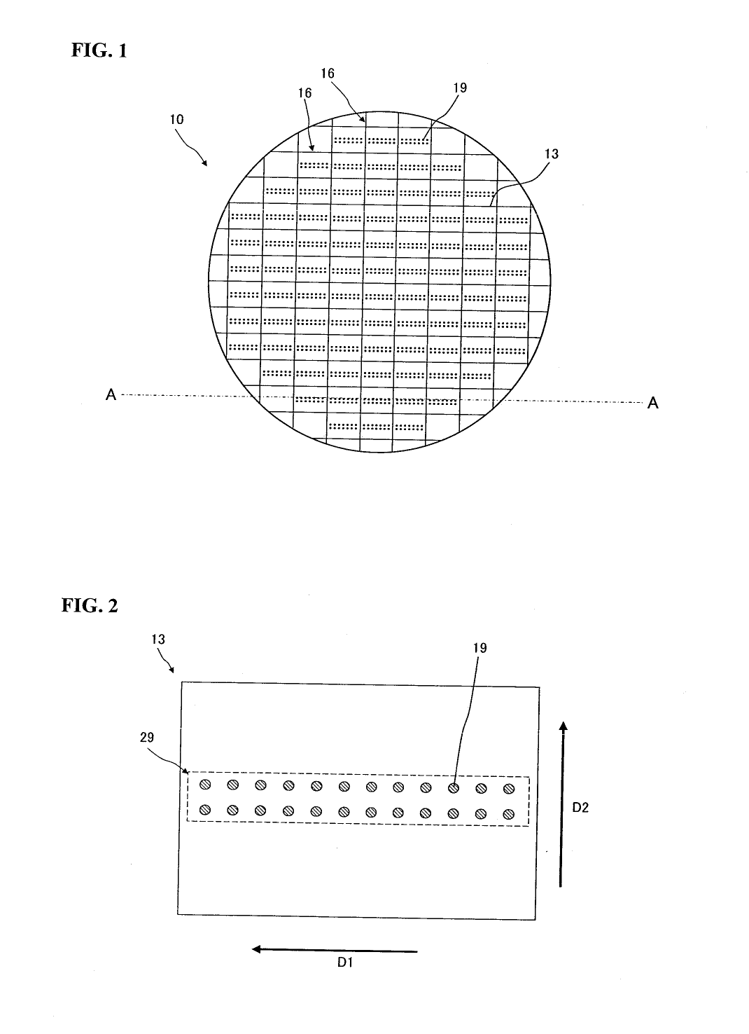

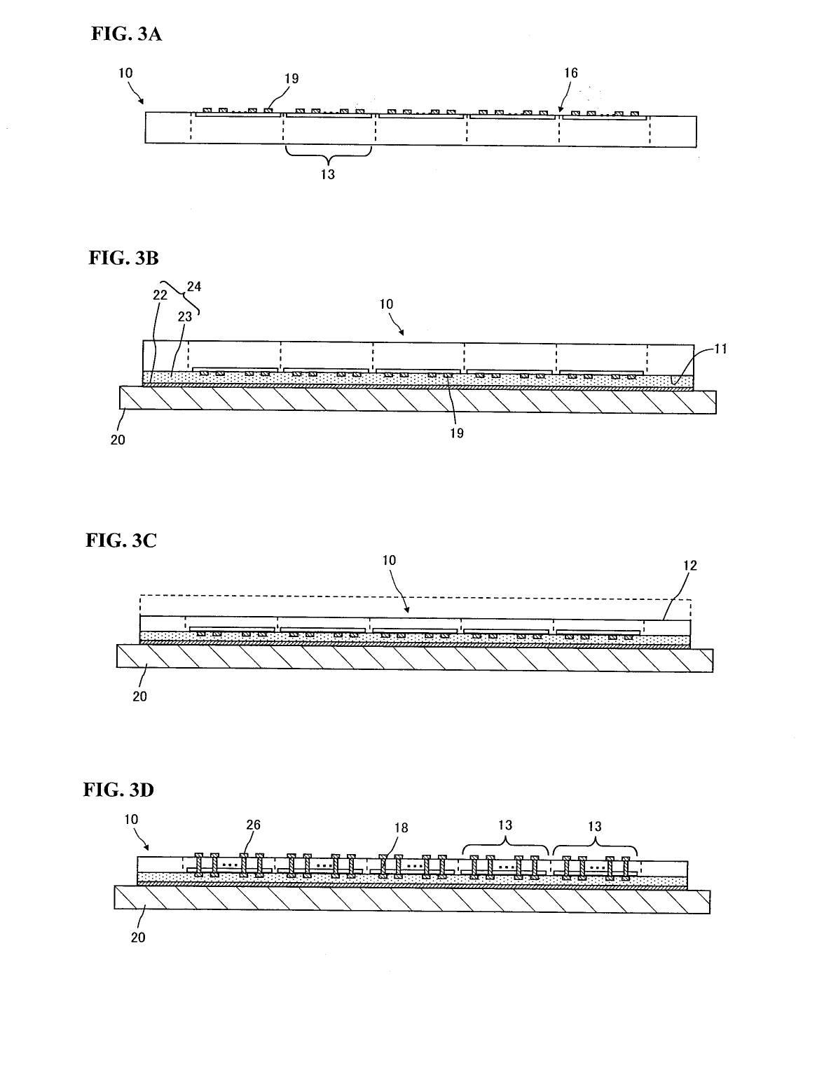

FIG. 1 is a plan view schematically illustrating the configuration of a semiconductor wafer. FIG. 2 illustrates the arrangement of bump electrodes in one semiconductor chip formed on the semiconductor wafer. FIG. 3A is a sectional view cut along the line A-A illustrated in FIG. 1. In FIGS. 3A to 3D, to simplify the drawings, some bump electrodes are omitted.

According to the method for manufacturing a semiconductor device of this embodiment, first, semiconductor wafer 10 illustrated in FIGS. 1 and 2 is prepared. Semiconductor wafer 10 includes a plurality of semiconductor chips 13 divided by dicing lines 16. In each semiconductor chip 13, a predetermined circuit such as a memory circuit, and an electrode pad can be formed. On the electrode pad, bump electrode 19 can be formed.

As illustrated in FIG. 2, for example, 12 rows and 2 columns of bump electrodes 19 are arranged in the center region of semiconductor chip 13. Bump electrodes 19 are arrayed in a matrix to constitute bump electrode group 29. The number of bump electrodes 19 in first direction D1 (hereinafter, may also be referred to as row direction) is larger than that in second direction D2 (hereinafter, may also be referred to as column direction). Bump electrodes 19 constituting bump electrode group 29 can be arranged at equal pitches. As illustrated in FIG. 1, for each semiconductor chip 13, it is preferred that the number of bump electrodes 19 in first direction D1 be larger than that in second direction D2. Semiconductor chip 13 can be formed into a roughly rectangular shape, and bump electrode group 29 can be arranged so that first direction D1 can be parallel to the long side of semiconductor chip 13. Bump electrode group 29 is formed of bump electrodes 19 arrayed, for example, in 12 rows and 2 columns in a lattice pattern with a 50 μm pitch.

Next, semiconductor wafer 10 is subjected to an intermediate process. FIGS. 3A to 3D illustrate a series of steps in the intermediate process. Semiconductor wafer 10 illustrated in FIG. 3A is, as illustrated in FIG. 3B, bonded to support 20, e.g., a glass substrate, on one surface of semiconductor wafer 10 via adhesive material 24. Any type of adhesive material 24 can be used as long as it can subsequently be peeled off. Adhesive material 24 can be stuck to one surface of semiconductor wafer 10 in second direction D2 from one end side of the semiconductor wafer in first direction D1.

In this embodiment, as a preferred example of peelable adhesive material 24, adhesive material 24 having two layers, namely, first adhesive layer 22 and second adhesive layer 23, is used. First adhesive layer 22 covers bump electrodes 19 formed on first surface 11 of semiconductor wafer 10. Any type of first adhesive layer 22 can be used as long as it can protect first surface 11 of semiconductor wafer 10, particularly, bump electrodes 19. First adhesive layer 22 can be, for example, an ultraviolet curable acrylic adhesive material. When bump electrode 19 has a height of about 20 micrometers, first adhesive layer 22 needs to be formed with a thickness of about 50 micrometers.

Second adhesive layer 23 is in contact with support 20. Second adhesive layer 23 can be a type that volatilizes when irradiated with specific energy, for example laser light, as in the case of LTHC (manufactured by Sumitomo 3M Limited). Alternatively, second adhesive layer 23 can be a type whose adhesive force is reduced when irradiated with specific energy. As example of such an adhesive layer is one whose adhesive force has been reduced by heat or light.

As illustrated in FIG. 3C, second surface 12 of semiconductor wafer 10 held on support 20, namely, a surface opposite first surface 11, is ground by back grinding. This thins semiconductor wafer 10 to a predetermined thickness of about, e.g., 50 micrometers.

Then, as illustrated in FIG. 3D, penetrating electrodes 18 and bump electrodes (rear surface bumps) 26 are formed on second surface 12 of semiconductor wafer 10. Penetrating electrode 18 can be formed by boring a hole in a part of semiconductor wafer 10 corresponding to an electrode pad and burying the hole with a metal by plating

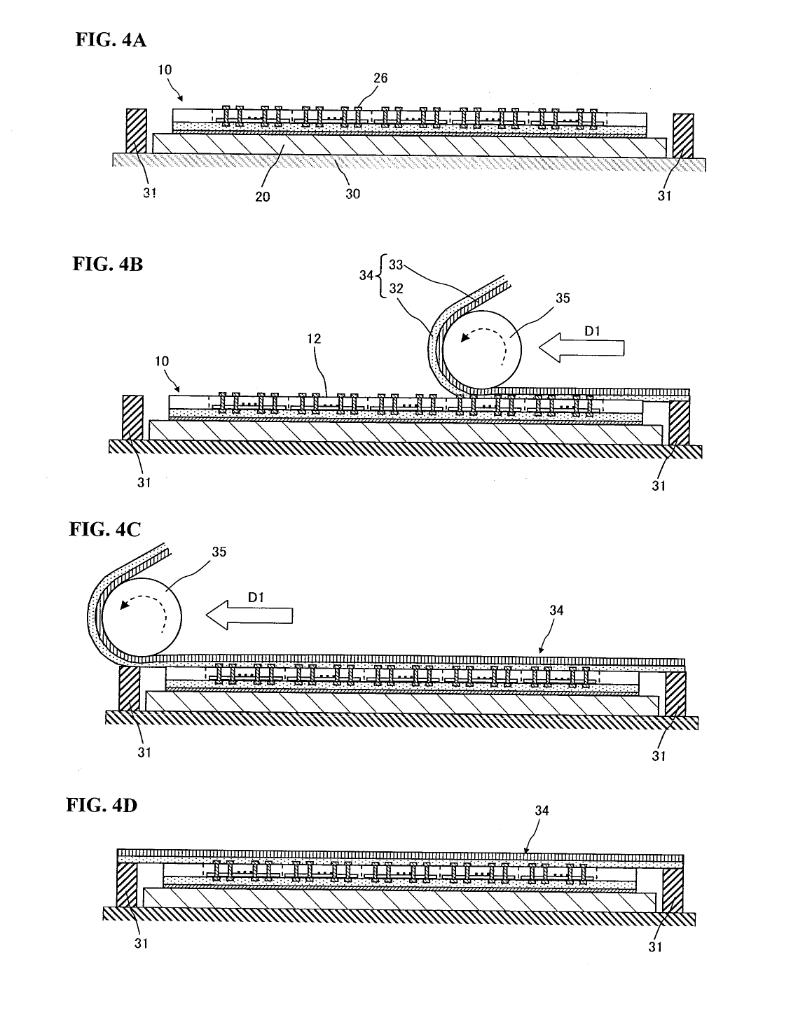

Next, semiconductor wafer 10 is subjected to demounting process. FIGS. 4A to 4D are sectional views illustrating the demounting process. In the demounting process, as illustrated in FIG. 4A, support 20 for holding semiconductor wafer 10 is placed on stage 30, and frame-shaped member 31 is placed outside semiconductor wafer 10. Frame-shaped member 31 surrounds semiconductor wafer 10. The upper surface of frame-shaped member 31 is located at a height approximately equal to that of the upper surface of semiconductor wafer 10.

Dicing tape 34 is attached to frame-shaped member 31 and second surface 12 of semiconductor wafer 10. Dicing tape 34 can be attached by a roller. It is preferred, as illustrated in FIGS. 4B and 4C, that dicing tape 34 be made to continuously attached along first direction D1 from one end of semiconductor wafer 10 toward the other end. FIG. 4D illustrates semiconductor wafer 10 to which dicing tape 34 has been made to adhere.

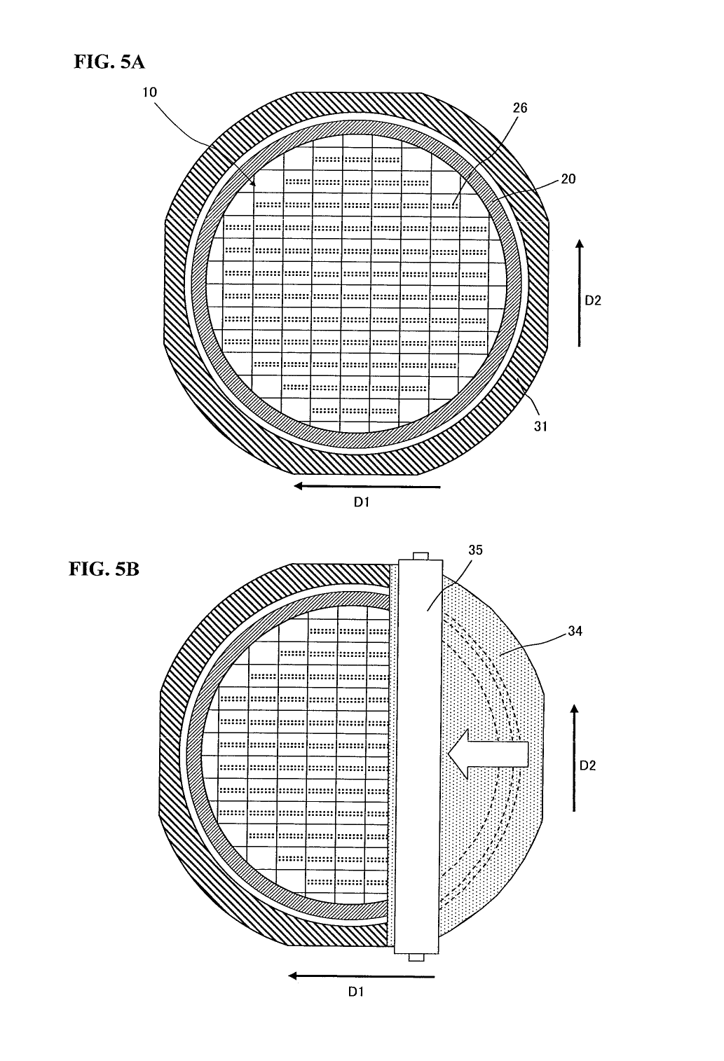

In this embodiment, as illustrated in FIGS. 5A and 5B, dicing tape 34 is stuck in first direction D1 from one end side in first direction D1 where the number of arrayed bump electrodes 26 is large. In this case, roller 35 is pressed to semiconductor wafer 10, and air between dicing tape 34 and semiconductor wafer 10 is pushed out by roller 35.

Sticking dicing tape 34 in first direction D1 where the number of arrayed bump electrodes 26 is large enables satisfactory pushing-out of the air between dicing tape 34 and semiconductor wafer 10. As a result, generation of any void between dicing tape 34 and semiconductor wafer 10 can be prevented.

When dicing tape 34 is attached along second direction D2 orthogonal to first direction D1, the air advancing in the second direction may be trapped in the column of bump electrodes 26 arrayed in first direction D1. In this case, a large void may be generated near bump electrode 26 of semiconductor chip 13.

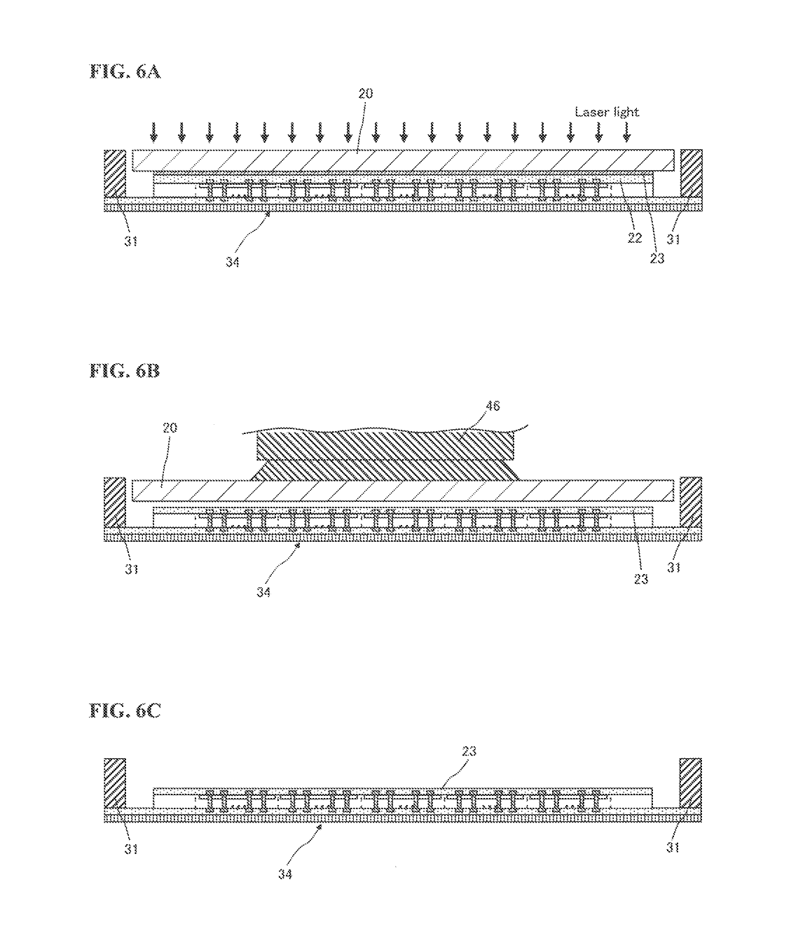

Then, as illustrated in FIG. 6A, laser light is applied from support 20 side, and second adhesive layer 23 of support 20 side is accordingly volatilized to be removed. Support 20 is then adsorbed by, e.g., adsorption collet 46, to be removed from semiconductor wafer 10 (refer to FIGS. 6B and 6C). First adhesive layer 22 left on second surface 12 of semiconductor wafer 10 is then peeled off by using peeling tape 37.

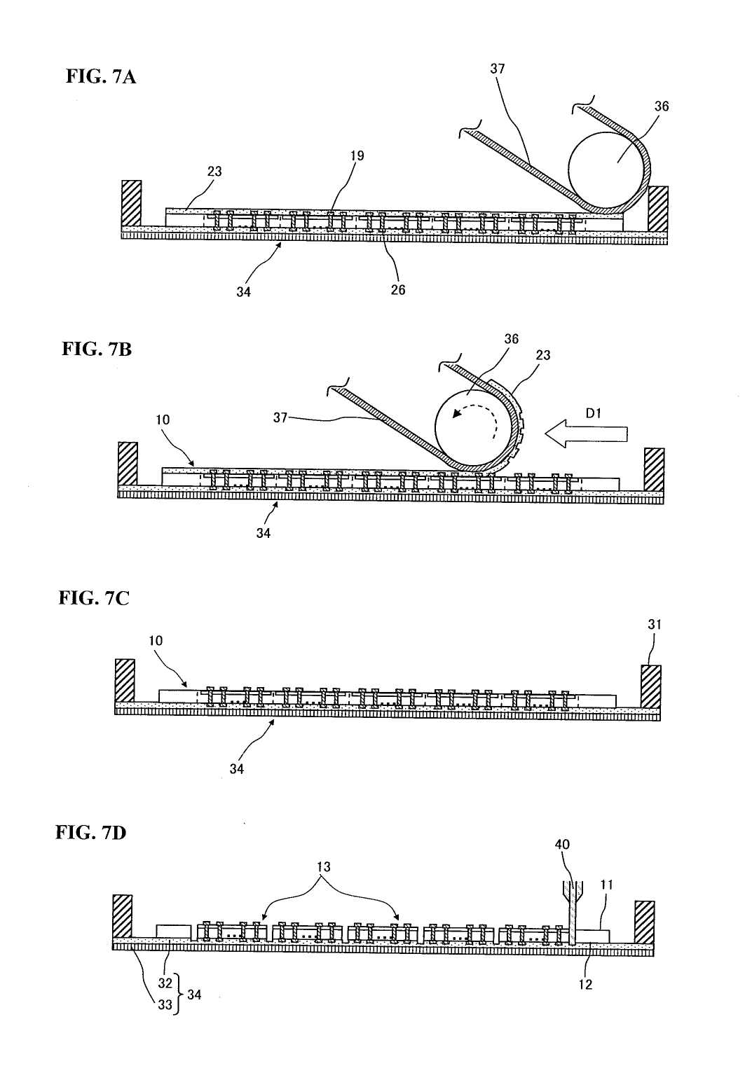

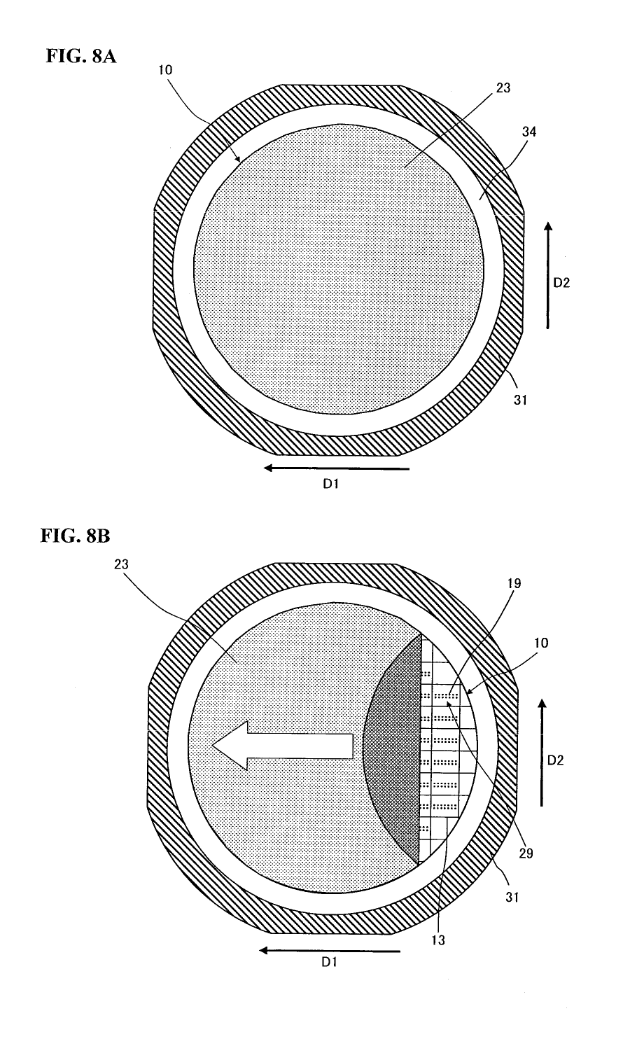

FIGS. 7A to 7D illustrate a method for peeling off second adhesive layer 23 from semiconductor wafer 10. Second adhesive layer 23 is peeled off from semiconductor wafer 10 in first direction D1 from one end side of semiconductor wafer 10 in first direction D1 where the number of bump electrodes 19 is large (refer to FIGS. 7A and 7B). Specifically, as illustrated in FIGS. 8A and 8B, it is preferred that roller 36 be moved in first direction D1 from one end side of semiconductor wafer 10 while peeling tape 37 is pressed to second adhesive layer 23 on semiconductor wafer 10 by roller 36.

As described above, second adhesive layer 23 is thin at the place where there is bump electrode 19. The thin part of second adhesive layer 23 accordingly extends in first direction D1 where bump electrodes 19 are arrayed in first direction D1. Consequently, a cut extending in first direction D1 easily occurs in second adhesive layer 23. On the other hand, it is difficult for cut to occur in second direction D2.

Thus, by peeling off second adhesive layer 23 from semiconductor wafer 10 in first direction D1, cuts can be prevented from occurring in second adhesive layer 23 to ensure that second adhesive layer 23 does not remain on the semiconductor wafer. Even when a cut occurs in second adhesive layer 23 in first direction D1, second adhesive layer 23 is torn off in first direction D1, and hence it is difficult for second adhesive layer 23 to remain on semiconductor wafer 10. This enables satisfactory peeling-off of second layer 23 from semiconductor wafer 10, providing an advantage that manufacturing turn-around time (TAT) during the demounting process can be shortened.

On the other hand, if second adhesive layer 23 is torn off in second direction D2, when a cut occurs in second adhesive layer 23 in the first direction, second adhesive layer 23 may remain on semiconductor wafer 10.

Further, the semiconductor wafer has low resistance to bending in the second direction, while it has high resistance to bending in first direction D1 where the number of penetrating electrodes 18 is large. This is advantageous in that by peeing off second adhesive layer 23 from semiconductor wafer 10 in first direction D1, the occurring of cracks in semiconductor chip 13 is reduced during the peeing-off of the adhesive layer. Thus, reliability of manufactured semiconductor chip can be improved.

Next, semiconductor wafer 10 held by dicing tape 34 stuck to frame-shaped member 31 illustrated in FIG. 7C is subjected to a dicing process. FIG. 7D is a sectional view illustrating the dicing process. During the dicing process, semiconductor wafer 10 is cut by the dicing lines to be divided into semiconductor chips 13. Semiconductor wafer 10 is cut by, for example, dicing blade 40 that rotates at a high speed.

It is preferred that semiconductor wafer 10 be cut from second surface 12 of semiconductor wafer 10 to a part of adhesive layer 32 constituting dicing tape 34. This divides semiconductor wafer 10 into semiconductor chips.

According to this embodiment, by sticking the dicing tape in first direction D1 where the number of bump electrodes is large, semiconductor wafer 10 is satisfactorily held by the dicing tape. As a result, the occurrence of chipping is reduced, enabling satisfactory cutting of the semiconductor wafer.

Then, semiconductor chips 13 divided on tape base material 33 constituting dicing tape 34 are picked up. To pick up semiconductor chips 13, the adsorption collet having suction holes to vacuum-adsorbing semiconductor chips 13 can be used. The semiconductor device is manufactured through the abovementioned process.

It is preferred that tape base material 33 constituting dicing tape 34 be a durable tape. It is preferred that adhesive force of adhesive layer 32, that constitutes dicing tape 34, be reduced in adhesive force by irradiation with specific energy such as ultraviolet rays. In this case, it is preferred that semiconductor chips 13 be picked up after the adhesive force of adhesive layer 32 has been reduced by irradiation with specific energy such as ultraviolet rays.

To pick up semiconductor chips 13, it is preferred that semiconductor chips 13 be raised from surface 11 of dicing tape 34 opposite one surface 12 to which semiconductor chips 13 have been bonded by, for example, a raising mechanism that will be used to be picked up semiconductor chips 13. In this case, tape base material 33 is bent when it is flexible, and thus semiconductor chips 13 can be easily picked up.

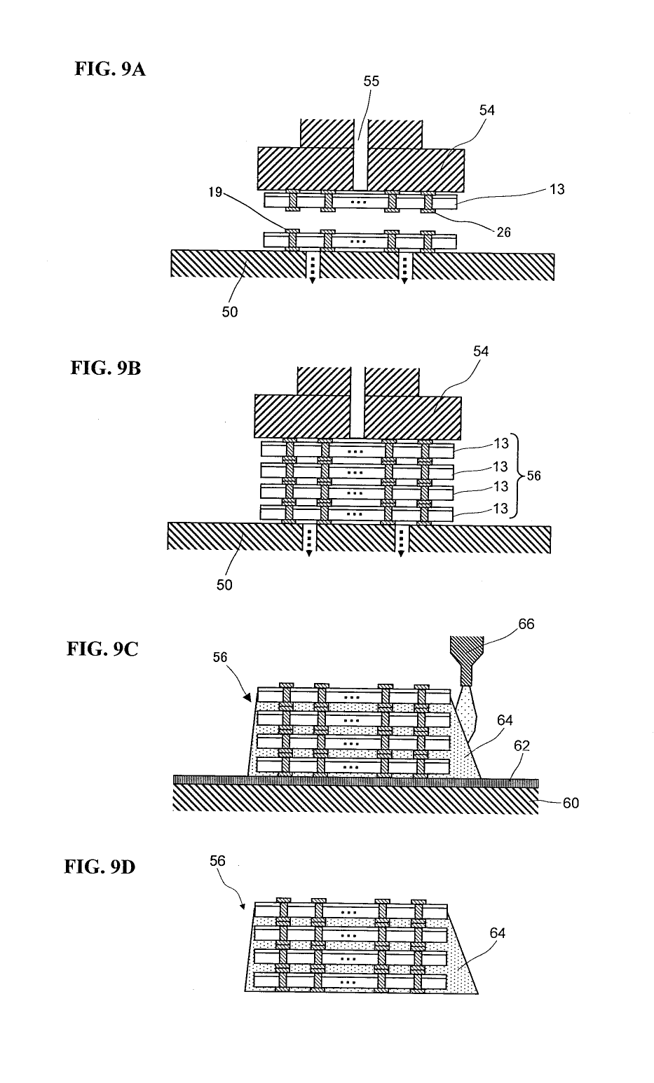

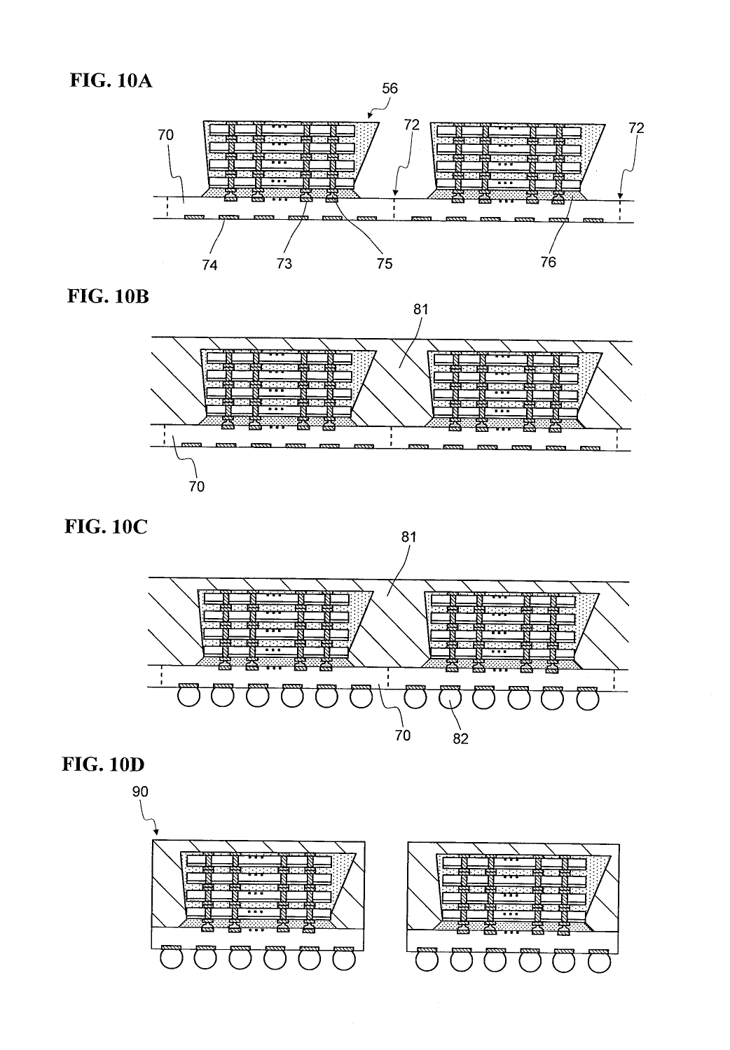

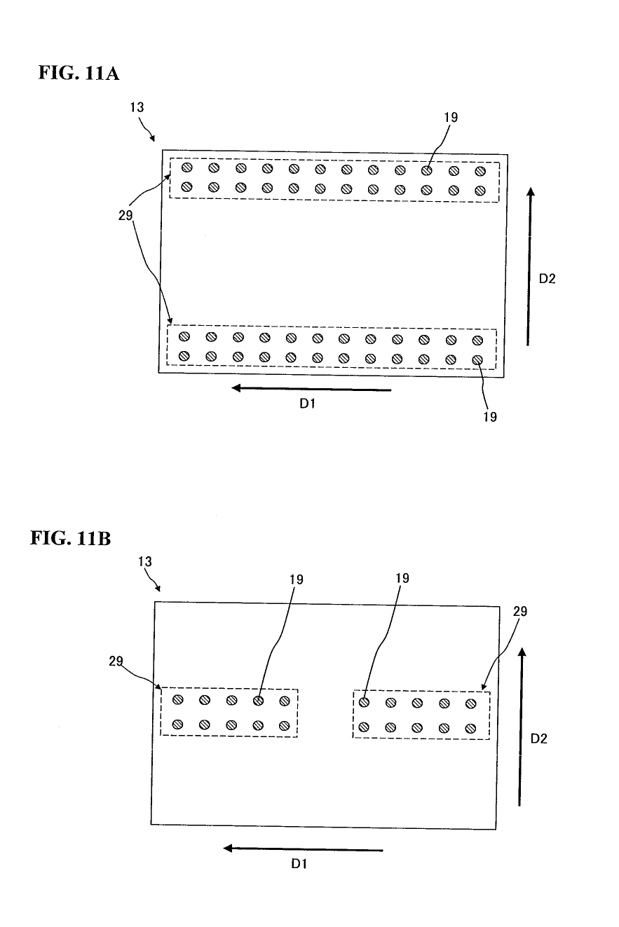

Hereinafter, an example of a method for manufacturing a CoC semiconductor device by using semiconductor chips 13 is described. FIGS. 9A to 9D and FIGS. 10A to 10D are sectional views illustrating the assembling process of the CoC semiconductor device.

Semiconductor chip 13 is, as illustrated in FIG. 9A, mounted on bonding stage 50 with the surface where the circuits and bump electrodes 19 have been formed turned up. It is preferred that bonding stage 50 include a heating mechanism such as a heater (not illustrated). The heating mechanism can heat semiconductor chip 13 held on bonding stage 50 to a predetermined temperature, e.g., 100° C.

Then, as illustrated in FIG. 9A, 2nd-stage semiconductor chip 13 is mounted on 1st-stage semiconductor chip 13 held on bonding stage 50. 2nd-stage semiconductor chip 13 is similar in configuration to 1st-stage semiconductor chip 13. In this case, a load is applied to 2nd-stage semiconductor chip 13 while heating semiconductor chip 13 to a high temperature, e.g., about 300° C., by bonding tool 54 including a heater. Bump electrodes 19 formed on 1st-stage semiconductor chip 13 and bump electrodes 26 formed on 2nd-stage semiconductor chip 13 are accordingly connected electrically by thermocompression bonding. When 2nd-stage semiconductor chip 13 is bonded to 1st-stage semiconductor chip 13, an ultrasonic wave can be further applied to the bonded part.

Similarly, 3rd-stage and 4th-stage semiconductor chips 13 are mounted on 2nd-stage semiconductor chip 13 (refer to FIG. 9B). 3rd-stage and 4th-stage semiconductor chips 13 can be similar in configuration to 1st-stage semiconductor chip 13. As a result, chip laminated body 56 where four semiconductor chips 13 are stacked and mounted is formed. Not limited to this, however, the number of semiconductor chips 13 constituting chip laminated body 56 needs to be at least 2.

Then, as illustrated in FIG. 9C, chip laminated body 56 is mounted on coating sheet 62 stuck to another stage 60 (hereinafter, referred to as coating stage). It is preferred that, for coating sheet 62, a material having low wettability to an underfill material to reinforce joining of semiconductor chips 13 be used. As such coating sheet 62, for example, a fluorinated sheet or a sheet to which a silicon adhesive material is made to adhere is used.

As illustrated in FIG. 9C, underfill material 64 is supplied near the end of chip laminated body 56 on coating sheet 62. Underfill material 64 fills gaps among semiconductor chips 13 by a capillary phenomenon. Underfill material 64 can be supplied from, for example, dispenser 66.

When coating sheet 62 is made of a material having low wettability to underfill material 64, there is an advantage in that spreading of underfill material 64 on coating sheet 62 is prevented which reduces a fillet width. By using coating sheet 62, sticking of underfill material 64 to coating stage 60 is prevented.

After completion of filling with underfill material 64, chip laminated body 56 is cured together with coating sheet 62 at a predetermined temperature, e.g., about 150° C. This hardens underfill material 64. Underfill material 64 is accordingly formed around chip laminated body 56 and between semiconductor chips 13.

As illustrated in FIG. 9D, after underfill material 64 has become hardened, chip laminated body 56 is picked up from coating sheet 62. When coating sheet 62 is made of a material having low wettability to underfill material 64, there is an advantage in that chip laminated body 56 can be easily picked up.

Next, wiring board 70 is prepared to amount chip laminated body 56 (refer to FIG. 10A). Wiring board 70 can be, for example, a glass epoxy wiring board having a thickness of about 0.14 millimeters. Wiring board 70 includes a plurality of product forming parts arranged in a matrix. The product forming parts are divided by dicing lines 72. A predetermined wiring pattern is formed in each product forming part. The wiring pattern is partially covered with an insulating film such as a solder resist.

Connection pad 73 is located on one surface of wiring board 70, the part where the wiring pattern is exposed from the solder resist. Land 74 is located on the other surface of wiring board 70, the part where a wire is exposed from the solder resist. Connection pad 73 and its corresponding land 74 are electrically connected by a wire formed on wiring board 70.

A wire bump (convex bump) 75 is formed on connection pad 73 of wiring board 70. Wire bump 75 is made of, for example, gold (Au) or copper (Cu). A wire bonding device (not illustrated) melts the leading end of the wire, and thermocompresses the wire having a ball formed at the leading end on connection pad 73 of wiring board 70 by an ultrasonic wave. The trailing end of the wire is then cut off to form wire bump 75.

Wire bump 75 is convex-shaped, and hence the area of a connection part between wire bump 75 and semiconductor chip 13 is smaller than that of the connection part between wire bump 75 and wiring board 70. This enables miniaturization and pitch narrowing of conductors (penetrating wires) 18 electrically connected to the bump electrodes that constitutes the bump electrode group in the semiconductor chip.

In the abovementioned example, to facilitate the connection between chip laminated body 56 and wiring board 70, wire bump 75 is formed on connection pad 73 of wiring board 70. However, the electrode of chip laminated body 56 and connection pad 73 of wiring board 70 can be directly connected together. In this case, the electrode of chip laminated body 56 corresponds to bump electrode 19 or 26 of semiconductor chip 13 that constitutes the chip laminated body.

When chip laminated body 56 is mounted on wiring board 70, it is preferred that wiring board 70 be coated with insulating adhesive member 76 such as nonconductive paste (NCP). Adhesive member 76 can be applied by a dispenser.

Chip laminated body 56 is mounted on each product that forms part of wiring board 70. To mount chip laminated body 56, for example, the bonding tool that includes the heating mechanism (not illustrated) can be used. The bump electrode exposed on the surface of chip laminated body 56 is thermocompressed on corresponding connection pad 73 of wiring board70. In this case, adhesive member 76 spreads on wiring board 70 to fill a gap between chip laminated body 56 and wiring board 70.

It is preferred that underfill material 64 around chip laminated body 56 be tapered. That reason for is because the rising of adhesive member 76 is prevented during the operation when chip laminated body 56 is mounted on wiring board 70. As a result, cracks or joining failures of chip laminated body 56 that are caused by adhesive material 76 adhering to the bonding tool are reduced.

Then, as illustrated in FIG. 10B, chip laminated body 56 that is mounted on wiring board 70 is sealed (molding process). During the molding process, wiring board 70 is set in a mold that includes an upper die and a lower die by a transfer molding device (not illustrated). The mold includes a cavity that is formed to cover the plurality of chip laminated bodies 56 en bloc, and wiring board 70 is located in the cavity.

Sealing member 8 that has been melted by heat is then injected into the cavity to seal chip laminated body 56 on wiring board 70. For sealing member 81, for example, a thermosetting resin such as an epoxy resin is used.

In a state where sealing member 81 has been supplied to one surface side of wiring board 70, sealing member 81 is cured at a predetermined temperature, e.g., about 180° C., to be thermally hardened. Sealing member 81 is accordingly formed to cover the plurality of chip laminated bodies 56 en bloc on wiring board 70. Then, sealing member 81 is baked at a predetermined temperature by the surrounding mold to be completely hardened.

Underfill material 64 is disposed beforehand to fill the gap between semiconductor chips 13 that constitute chip laminated body 56. This can prevent the generation of voids between semiconductor chips 13 during the molding process.

As illustrated in FIG. 10C, external terminal 82 is formed in land 74 formed on wiring board 70. For external terminal 82, a conductive metal ball such as solder is used. For example, the metal ball is mounted on land 74 of wiring board 70 by a mounting tool that includes suction holes to adsorb and hold a plurality of metal balls. Specifically, fluxes are transferred to the plurality of metal balls held by the mounting tool, and the metal balls are mounted en bloc on the plurality of lands 74 on wiring board 70. After the metal balls have been mounted, wiring board 70 is subjected to reflowing to form external terminal 82.

Then, as illustrated in FIG. 10D, wiring board 70 on which external terminal 82 has been formed is separated along the dicing lines into semiconductor devices 90 (substrate dicing process). During the substrate dicing process, first, the dicing tape is adhered to one surface of sealing body 81 that is formed on wiring board 70, and wiring board 70 is supported by the dicing tape.

Then, by the dicing blade of a dicing device (not illustrated), wiring board 70 is then cut vertically and horizontally along the dicing lines. Wiring board 70 is accordingly separated for each semiconductor device 90. A plurality of CoC semiconductor devices can be manufactured when semiconductor devices 90, that include chip laminated bodies 56, are picked up from the dicing tape.

The preferred embodiment of the present invention has been described. Needless to say, however, the present invention is not limited to the embodiment. Various changes can be made without departing from the spirit and scope of the invention.

Referring to FIGS. 1 and 2, the method for manufacturing the semiconductor device by using semiconductor wafer 10 having the plurality of semiconductor chips 13 in the center regions of which bump electrode groups 29 are arranged has been described. However, as illustrated in FIG. 11A, two bump electrode groups 29 can be arranged near the two opposing ends of semiconductor chip 13. Each bump electrode group 29 is formed of bump electrodes 19 arrayed, for example, in 12 rows and 2 columns in a lattice pattern with a 50 μm pitch. Two bump electrode groups 29 are placed side by side along lateral direction D2. It is preferable that distance between bump electrode groups 29 be larger than the pitch between bump electrodes 19 forming bump electrode groups 19 and not smaller than 200 μm. Each bump electrode group 29 is positioned in the vicinity of an end side, e.g., one of the longer sides of semiconductor chip 13.

As illustrated in FIG. 11B, in the center region of semiconductor chip 13, bump electrode groups 29 arranged at a pitch larger than that between bump electrodes 19 can be located in first direction D1. Three or more bump electrode groups 29 can be arranged. Each bump electrode group 29 is formed of bump electrodes 19 arrayed, for example, in 5 rows and 2 columns in a lattice pattern with a 50 μm pitch. In the present exemplary embodiment, a plurality of bump electrode groups 29 are disposed by being spaced apart from each other by a distance of 700 μm or less in longitudinal direction D1. Distance between each adjacent pair of bump electrode groups 29 is larger than the pitch between bump electrodes 19 forming the bump electrode groups.

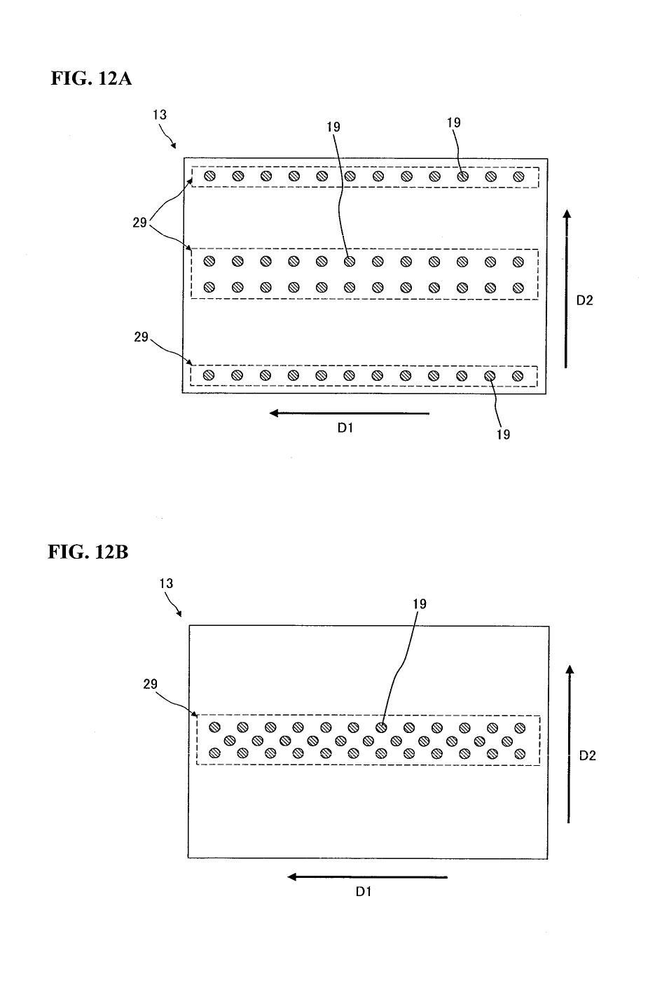

As illustrated in FIG. 12A, bump electrode groups 29 can be arranged in the center region of semiconductor chip 13 and near two ends parallel to first direction D1. As illustrated in FIG. 12B, in the center region of semiconductor chip 13, bump electrodes 19 can be arranged in a staggered manner.

In semiconductor chip 13 illustrated in FIGS. 11A and 11B and FIGS. 12A and 12B, it is preferred that pitches between bump electrodes 19 that constitute one bump electrode group 29 be equal to one another. In any case, in bump electrode group 29, bump electrodes 19 are arrayed in the matrix so that the number of bump electrodes 19 in second direction D2 can be smaller than that in first direction D1. In this case, by adhering the tape member to the semiconductor wafer along first direction D1 from one end side of the semiconductor wafer in first direction D1, the tape member can be made to adhere satisfactorily. Further, by peeling off the adhesive layer from semiconductor wafer 10 along first direction D1 from one end side of the semiconductor wafer in first direction D1, the adhesive layer can be satisfactorily peeled off.

As illustrated in FIGS. 11A and 11B and FIGS. 12A and 12B, it is preferred that a pitch between one bump electrode group 29 and the other adjacent bump electrode 29 be larger than that between the bump electrodes constituting the bump electrode group.

According to the embodiment, adhesive layer 23 is peeled off after the removal of support 20. However, the present invention can be applied to peeling-off of an adhesive tape having an adhesive layer adhere to the bump forming surface of semiconductor wafer 10 that includes semiconductor chip 13 having bump electrodes and penetrating electrodes, for example, a wafer backgrind (BG) protective tape.

According to the embodiment, the dicing tape is adhere to the bump surface of semiconductor wafer 10 having semiconductor chip 13 having the bump electrodes. However, the present invention can be applied to an adhesive tape that has an adhesive layer that adheres to the bump forming surface, for example, a wafer BG protective tape.

The embodiment has been directed to a semiconductor wafer that has a semiconductor chip (memory chip) in which the memory circuit has been formed. However, the present invention can be applied to a general semiconductor wafer that includes a semiconductor chip having bump electrode group 29 where the number of bump electrodes is larger in first direction D1 than that in second direction D2.

Examples of the disclosed invention are as follows.

[Appendix 1]

A method for manufacturing a semiconductor device includes: preparing a semiconductor wafer that includes at least one semiconductor chip having a bump electrode group formed by arraying bump electrodes in a matrix, the number of the bump electrodes in a second direction being smaller than that in a first direction; and

adhering a tape member to the semiconductor wafer along the first direction from one end side of the semiconductor wafer.

[Appendix 2]

The method for manufacturing a semiconductor device according to Appendix 1, in which when the tape member is adhered, in a state where the tape member is pressed to the semiconductor wafer by a roller, the roller is moved along the first direction from the one end side of the semiconductor wafer.

[Appendix 3]

The method for manufacturing a semiconductor device according to Appendix 1, in which pitches between the bump electrodes constituting the bump electrode group are equal to one another.

While preferred embodiments of the present invention have been described using specific terms, such description is for illustrative purposes only, and it is to be understood that changes and variations may be made without departing from the spirit or scope of the following claims.

What is claimed is:

1. A method for manufacturing a semiconductor device, comprising:
preparing a semiconductor wafer that includes at least one semiconductor chip having a bump electrode group formed by arraying bump electrodes in a matrix, the number of the bump electrodes in a second direction being smaller than that in a first direction, and an adhesive layer formed on one surface having the bump electrode group; and
peeling off the adhesive layer from the semiconductor wafer along the first direction from one end side of the semiconductor wafer.

2. The method for manufacturing a semiconductor device according to claim 1, wherein when the adhesive layer is peeled off, in a state where a peeling tape is pressed to the adhesive layer on the semiconductor wafer by a roller, the roller is moved along the first direction from the one end side of the semiconductor wafer.

3. The method for manufacturing a semiconductor device according to claim 1, wherein pitches between the bump electrodes constituting the bump electrode group are equal to one another.

4. The method for manufacturing a semiconductor device according to claim 1, further comprising adhering the adhesive layer to the one surface of the semiconductor wafer having the at least one semiconductor chip along the first direction from the one end side of the semiconductor wafer in the first direction.

5. The method for manufacturing a semiconductor device according to claim 3, wherein:
said at least one semiconductor chip has a plurality of bump electrode groups; and
a pitch between one of the bump electrode groups and the other adjacent bump electrode group is larger than that between the bump electrodes constituting the bump electrode group.

6. The method for manufacturing a semiconductor device according to claim 1, wherein:
said at least one semiconductor chip is substantially rectangular; and
the bump electrode group is arranged so that the first direction is parallel to a long side of the semiconductor chip.

7. The method for manufacturing a semiconductor device according to claim 1, wherein said at least one semiconductor chip has a penetrating wire electrically connected to the bump electrodes of the bump electrode group.

8. The method for manufacturing a semiconductor device according to claim 2, wherein:
the adhesive layer is made of an adhesive material whose adhesive force is reduced by irradiation with specific energy; and
the adhesive layer is irradiated so that the adhesive force of the adhesive layer becomes weaker than the adhesive force of the peeling tape, and then the adhesive layer peeled off.

9. A method comprising:
preparing a semiconductor chip including an upper surface, a lower surface opposite to the upper surface and a first bump group formed on the upper surface, the first bump group comprises a plurality of first bumps arranged in a plurality of first straight lines with a certain pitch, a number of the first bumps in each of the plurality of first straight lines is larger than a number of the plurality of first straight lines;
providing an adhesive layer on the upper surface;
removing the adhesive layer from the semiconductor chip so as to peel off the adhesive layer along the plurality of the first straight lines from one end of the semiconductor chip.

10. The method according to claim 9, wherein the semiconductor chip includes a second bump group formed on the upper surface, the second bump group is apart from the first bump group with a pitch that is larger than the certain pitch.

11. The method according to claim 10, wherein the second bump group comprises a plurality of second bumps arranged in a plurality of second straight lines with a certain pitch, a number of the second bumps in each of the plurality of second straight lines is larger than a number of the plurality of second straight lines, and the plurality of the second straight lines are substantially parallel to the plurality of first straight lines.

12. The method according to claim 10, wherein the second bump group is apart from the first bump group with a distance along an extending direction of the first straight lines, the distance is larger than the certain pitch.

13. The method according to claim 10, wherein the second bump group is apart from the first bump group with a distance along an extending direction of the second straight lines, the distance is larger than the certain pitch.

14. The method according to claim 9, further comprising:
attaching a supporting tape on the lower surface of the semiconductor chip so as to continuously attach along the first straight lines from one end of the semiconductor chip, before removing the adhesive layer from the semiconductor chip.

15. The method according to claim 9, wherein when the adhesive layer is peeled off, in a state where a peeling tape is pressed to the adhesive layer on the semiconductor chip by a roller, the roller is moved along the first straight lines from the one end of the semiconductor chip.

16. The method according to claim 9, wherein the semiconductor chip is a rectangular shape, and
the first bump group is arranged so that each of the first straight lines is parallel to a long side of the semiconductor chip.

17. The method according to claim 9, wherein the semiconductor chip includes a plurality of penetrating wires electrically connected to the first bumps.

18. The method according to claim 15, wherein the adhesive layer is made of an adhesive material whose adhesive force is reduced by irradiation with specific energy, and
the adhesive layer is irradiated so that the adhesive force of the adhesive layer becomes weaker than the adhesive force of the peeling tape, and then the adhesive layer peeled off.

19. A method comprising;
preparing a semiconductor wafer including a plurality of semiconductor chips, each of semiconductor chips including a plurality of first bumps formed on a first surface, a number of bumps of the plurality of the first bumps arranged in a first direction being larger than that of the plurality of the first bumps arranged in a second direction different from the first direction;
providing a support substrate on the first surface of the semiconductor wafer with an adhesive layer;
forming a plurality of second bumps on a second surface of the semiconductor wafer opposite to the first surface, at least one of the second bumps being electrically connected to a corresponding one of the first bumps via conductors;
removing the support substrate from the semiconductor wafer so that the adhesive layer remains on the semiconductor wafer; and
removing the adhesive layer from the semiconductor wafer so as to peel off the adhesive layer along the first direction from one end of the semiconductor wafer.

20. The method according to claim 19, further comprising:
attaching a supporting tape on the second surface so as to continuously attach along the first direction from one end of the semiconductor wafer before removing the supporting substrate from the semiconductor wafer.
